(19) United States
(12) Patent Application Publication
(10) Pub. No.: US 2018/0277693 A1
(43) Pub. Date: Sep. 27, 2018

(54) Method of Manufacturing a Solar Cell

(71) Applicant: Tempress IP B.V., Vaassen (NL)

(72) Inventor: Ronald Cornelis Gerard Naber, Vaassen (NL)

(21) Appl. No.: 15/762,483

(22) PCT Filed: Sep. 30, 2016
(86) PCT No.: PCT/NL2016/000017

§ 371 Date: Mar. 22, 2018

(30) Foreign Application Priority Data
Sep. 30, 2015 (NL) 2015534

(51) Int. Cl. H01L 31/0224; H01L 31/18

(52) U.S. Cl. CPC H01L 31/02245; H01L 31/022458; H01L 31/1868; H01L 31/1864; H01L 31/1872

(57) ABSTRACT

The process for manufacturing a solar cell provides for so-called passivated contacts based on a layer of polysilicon layer onto a tunnel dielectric, such as a tunnel oxide. Herein, a treatment is carried out on the polysilicon layer as deposited by ion implantation so as to render to amorphized. This ion implantation simultaneously allows the provision of doped regions, particularly of phosphorus. Selectively recrystallized areas and untreated areas are then removed by etching, including unintentionally deposited polysilicon at the first side of the substrate. Further process steps may be carried out prior to or subsequent to this provision of a patterned and ion implanted polysilicon layer, so as to provide for instance a cell with an metal wrap-through (MWT) structure.

### FIELD OF THE INVENTION

The invention relates to a method of manufacturing a solar cell comprising the steps of:
providing a semiconductor substrate with a first side and an opposed second side;
depositing by means of chemical vapour deposition a layer of silicon on the second side;
doping the silicon layer by means of ion implantation, and
selectively removing part of the silicon layer by etching.

The invention also relates to a solar cell comprising a semiconductor substrate with a first side and an opposed second side, wherein a doped silicon layer overlies said electrically conductive region, and at least one metal contact is coupled to said doped silicon layer.

### BACKGROUND OF THE INVENTION

To advance solar cell manufacturing, particularly with a silicon substrate, and to obtain higher cell efficiencies, it is deemed necessary to reduce the amount of recombination losses of charge carriers inside the solar cell. One of the main causes of recombination losses in commercially available solar cells with monocrystalline silicon substrates are the metal contacts. These are made by screen printing pastes that contact the substrate using a fire-through technique. A known method to lower such recombination losses is the provision of a doped polysilicon layer as a buffer layer in between the silicon substrate and the metal contact in order to avoid direct contact between the two. A thin dielectric layer is suitably provided underneath the polysilicon layer which serves as a passivation layer, while being sufficiently thin to allow for tunnelling transport of charge carriers between the substrate and the polysilicon layer.

Such a solar cell and a method of manufacturing thereof are known from US2015/0162483A1. In the known method, the doped silicon layer is a an amorphous layer that is separated from the semiconductor substrate over a tunnel dielectric layer, for instance a silicon oxide layer with typically a thickness of about 2 nm. The amorphous silicon layer is suitably a hydrogenated silicon layer formed using a plasma-enhanced chemical vapour deposition (PECVD) process and includes Si—H covalent bonds throughout the layer. Dopants are provided by means of implantation, performed by ion beam implantation or plasma immersion implantation. Species of opposed conductivity type are implanted in two subsequent steps through a first and a second shadow mask, to define first and second implanted regions. Thereafter, the remaining non-implanted regions of the amorphous silicon layer are removed with a hydroxide-wet etchant that further forms trenches and/or texturizes exposed portions of the substrate. Subsequently, the implanted regions are annealed to form doped polycrystalline silicon emitter regions. Conductive contacts are thereafter fabricated to contact the first and second doped polycrystalline emitter regions. Suitably, the contacts are fabricated by first depositing and patterning an insulating layer to have openings and then forming one or more conductive layers in the openings.

As specified in paragraph [0076] of the said application, it was discovered that boron ion implantation of the silicon layer with a dose of at least 4E15 and energies between 5-15 keV can automatically impart high resistance to alkaline Si etch chemistries. However, no comparable selectivity was found to be possible using phosphorus ion implant conditions useful for doping n+ emitter regions. Therefore, US2015/0162483A1 proposes the application of very thin robust etch mask compositions exemplified by SiN, SiC or the use of polycarbosilane masking layers or the use of additional ion implantation of non-dopant species such as nitrogen or carbon.

This need for the application of a masking layer of either SiN, SiC or polycarbosilane or the use of additional implantation of non-dopant species is deemed disadvantageous. As observed in paragraph [0076] of the application, switching between plasma source chemistries (i.e. to deposit SiN or SiC) leads to compromised performance and particles, with more manufacturable solutions likely to involve sequential implant steps as part of an inline process flow based on stationary shadow masks equilibrated under each ion beam source. The implantation of nitrogen or carbon brings additional complexity in the application and could affect the electrical properties of the polysilicon layer negatively. Furthermore, the stated requirements for low energy implantation with a high dose of 8E15 cm-2 should render an extremely low throughput process, which therefore becomes very costly to implement in solar cell production.

One embodiment involves the use of graphite shadow masks. Such a process flow requires dedicated equipment and, as can be understood from the disclosure in [0076], it still has to be developed, so that it may well not succeed. In case of using a carbosilane layer, the implantation would be divided between the carbosilane layer and the underlying amorphous silicon layer. The etching is then to be assumed to be selective also for the carbosilane layer. Optionally, the doped portions of the carbosilane layer may be removed selectively to the underlying amorphous silicon layer portions after the first etching step. It is not disclosed how to achieve such selective etching. Furthermore, it is not clear how much doping will get into the amorphous silicon layer when the implantation is performed through a carbosilane layer.

### SUMMARY OF THE INVENTION

It is therefore an object of the present invention to provide an improved method and an improved process for the manufacture of solar cells that contain a doped polysilicon layer at the second side between the metal contact and the semiconductor, particularly silicon substrate, preferably separated from the substrate by means of a tunnel dielectric. Preferably, the manufacturing method should be efficient from a processing perspective, reducing yield loss and providing good quality at sufficiently low price.

According to a first aspect, the invention provides a method of manufacturing a solar cell comprising the steps of:
providing a semiconductor substrate with a first and a second side, which first side is intended for receiving incident light;
providing an electrically conductive region adjacent to the first side by means of diffusion of a dopant of a first conductivity type;
depositing by means of chemical vapour deposition silicon material, which forms a silicon layer at least on the second side and is further deposited at the first side;
treating at least part of the silicon layer at the second side, which treatment comprises ion implantation into the exposed silicon layer at the second side of a dopant species of a second conductivity type opposed to the first conductivity type, the second dopant species comprising phosphorus, so as to obtain first areas of the deposited silicon material that are amorphized and doped, and second untreated and/or crystalline areas in the deposited silicon material, and
removing the second areas of the silicon layer by etching, wherein the silicon layer on the first side forms part of the second areas that is etched away.

It has been understood in investigations leading towards the invention, that the stated problems may be resolved by generating a phase transition within deposited silicon material, so as to allow selective removal of part of the deposited silicon material by means of etching. The phase transition is particularly one between polycrystalline and amorphized material, but could alternatively be between amorphous and amorphized, doped material. In this manner, any unintentionally deposited silicon at the first side can be removed. Furthermore, the silicon layer at the second side may be selectively removed. It has been found by the inventors in investigations leading to the invention, that there is sufficient etch selectivity between the first areas and the second areas. It was furthermore found that the selective etch may be carried out without negative effects on a pre-existing dopant layer near to the first side of the substrate, for instance because this layer is still protected by a dopant layer (such as a silicate glass).

According to the invention, creation of amorphized first areas is achieved by ion implantation at the second side, which simultaneously results in doping of the silicon layer and suitably also doping of the underlying substrate. Particularly, the ion implantation is carried out in a directional manner, so as to apply the ion implantation only to the second side, or optionally to selective areas of the second side. Compared to the use of deposited dopant sources, a better control of dopant diffusion is achieved, and release of dopants into the surrounding atmosphere (i.e. substrate) during the anneal is prevented. Such release may lead to shunting effects, diminished solar cell performance and other artefacts.

In addition to achieving herewith an appropriate etch selectivity, it has been found that the use of implantation in a manner and with a doping dose configured for amorphisation, has a positive effect on the dopant distribution. Particularly, the amorphized silicon layer may be recrystallised by means of an anneal step. Such recrystallisation is based on solid phase epitaxial growth, for which some grains that survived the implantation process may serve as seeds. The dopant is integrated into the crystal lattice in this recrystallisation step. Therewith, the risk of recombination of charge carriers in the substrate is reduced.

More particularly, the silicon layer is provided in a Low-Pressure Chemical Vapour Deposition (LPCVD) process. The use of LPCVD has the advantage over other CVD processes such as plasma-enhanced CVD (PECVD), that better silicon layers are formed. Particularly, conformal layers are formed (conformal to any texture on the substrate). This reduces formation of pinholes. Such minimization of pinholes is relevant for the preferred embodiment of the present invention, wherein use is made of passivated contacts, because pinholes will lead to a higher recombination of charge carriers. The silicon layer is particularly deposited as polysilicon. However, because of subsequent amorphisation and recrystallisation in the course of an anneal, it is not deemed essential that the initially deposited layer is polysilicon or entirely polysilicon. Rather, it may be deemed beneficial to deposit the layer close to the transition temperature between amorphous and polysilicon. The benefit hereof is for instance that the grain size is quite uniform and not too big. In one embodiment, the deposition temperature is in the range of 500-650° C., for instance 520-600° C. or 580-620° C.

In this respect, it is believed by the inventor of the present invention that the application of hydrogenated amorphous silicon in the prior art may have a negative impact on the etch selectivity between phosphorus-implanted material and amorphous material. By using LPCVD for the deposition of the silicon layer, the resulting silicon layer has a different structure, and implantation of phosphorus will result in structural change resulting in etch selectivity between the amorphized material in the first areas and the material in the second areas. The use of LPCVD for the tunnel dielectric is deemed to contribute further to the excellent passivation properties achieved in the invention.

Furthermore, solar cells manufactured in accordance with the invention have been found to have an exceptionally good passivation performance for LPCVD poly-Si doped with ion implantation. Values for the open circuit voltage (V_{oc}) of higher than 730 mV have been obtained in experiments. This passivation performance is deemed due to the use of LPCVD and the extension of the implanted ions into the substrate to form a second electrically conductive region, more particularly a back surface field. Preferably a PECVD SiNx:H layer is applied on top of the recrystallised silicon layer, so as to provide atomic hydrogen during a subsequent heating step that can help passivate defects inside the substrate and applied layers. In one implementation, the ion implantation step is carried out at the second side in a mask-less manner, particularly using directional ion beams. This effectively results therein that the first area is on the second side of the substrate, whereas the second area is the first side of the substrate with its unintentional polysilicon deposition. Such an approach is feasible for a variety of cell concepts, including for instance solar cells of the conventional H-type electrode design at the first side, and solar cells with through-wafer vias (MWT-cells).

In a further embodiment of the method of the invention, the deposited silicon material (to be implanted) is in situ doped, and the implantation is used to increase a doping level of this silicon material and preferably also the underlying substrate. Therewith, the implantation dose required to obtain a specified resistivity is lowered. Still the implantation may be used to achieve the amorphisation desired for the selective etching.

In an advantageous embodiment, the implanted dopant is applied into the silicon layer and into the substrate. This provision is the result of both the implantation step and the anneal step. Importantly, it was found by the present inventor that the implantation of phosphorus into the substrate does not deteriorate any dielectric between the substrate and the silicon layer, more particularly a tunnel dielectric, such as a tunnel oxide. Even though the tunnel dielectric may have some damage initially, such damage is again removed during the anneal step, particularly for a dopant of n-type conductivity, such as phosphorus. The benefit of the implantation into the substrate is a reduction of the substrate resistivity.

Preferably, the dopant concentration ratio of the dopant in the silicon layer and the second electrically conductive region at the opposed side of the tunnel dielectric is at least two, more preferably at least 10 and suitably in the range of 100-1000. Such a concentration ratio is deemed beneficial for the enhancement of the passivation properties of the cell. It is observed that the second electrically conductive region is herein defined as the substrate region at the interface with the tunnel dielectric, more particularly within the first micrometer of the substrate. Particularly, the doped silicon layer is highly doped, particularly at least 1E18/cm³, more preferably at least 1E19/cm³ or even 0.5-5E20/cm³. It is also with such high dopant concentrations that good passivating properties are obtained, and hence that there is no flow of dopant atoms through the tunnel dielectric into the bulk of the substrate.

More preferably, in one implementation, the thickness of the silicon layer at the second side is at most 50 nm, more preferably at most 30 nm. Such a thickness of the silicon layer has been found to provide sufficient implantation into the substrate. Alternatively, the silicon layer may be larger than 50 nm, for instance a thickness in the order of 50-400 nm, preferably 100-250 nm.

In again a further embodiment, the anneal treatment is carried out so as to generate a thermal oxide. On top of the thermal oxide one or more passivating layers of silicon nitride, silicon oxynitride and silicon oxide may be deposited. Use of silicon nitride, that also functions as an antireflection coating (ARC) is preferred.

In a further implementation, the doped polysilicon areas at the second side are contacted by means of metal contacts. One preferred way of providing such contacts is the use of a metal paste, more particularly a silver paste. Such pastes are also known as fire-through pastes, in that they may be applied by screen printing without a need to separately create openings in the passivation layer, i.e. the paste will go through the passivation layer by itself. Surprisingly, it was found that the use of such metal paste provides a good contact to the LPCVD deposited, amorphised and recrystallised silicon layer. Particularly, it was found that the paste does not extend through the silicon layer and does not damage the underlying tunnel dielectric. Notwithstanding this preferred option, it is not excluded that the contacts may be provided in a different manner, for instance in a process using electroplating.

According to a second aspect, the invention relates to a solar cell comprising a semiconductor substrate with a first side and an opposed second side, which semiconductor substrate is provided with a first electrically conductive region of a first conductivity type adjacent to the first side and with a second electrically conductive region adjacent to the second side. The first electrically conductive region herein preferably contains boron and the second electrically conductive region comprises phosphorus. The first electrically conductive region constitutes an emitter and the second electrically conductive region constitutes a back surface field, wherein a doped silicon layer overlies said electrically conductive region and is separated therefrom through a tunnel dielectric, and at least one metal contact is coupled to said doped silicon layer. Herein, the doped silicon layer is a recrystallized, ion-implanted layer and the second electrically conductive region is doped by ion implantation.

The solar cell of the present invention may be provided at a lower cost price without loss in quality, and particularly with an excellent open circuit voltage and passivation performance. The presence of a conductive region in the substrate underlying a tunnel dielectric and one or more (poly)silicon-based contact layer, results in a low series resistance, as desired. An additional advantage is that the passivation is no longer fully dependent on the tunnel dielectric, which can be vulnerable and may be disrupted with minor contamination.

In a further embodiment, the resulting solar cell comprises metallic conductors extending in through-holes from the first to the second side of the substrate. One embodiment of such a solar cell is known as a metal-wrap-through (MWT) solar cell. Variations of the MWT solar cell, such as the EWT (Emitter-wrap-through) are however by no means excluded. Such a solar cell with a metallic conductor more particularly comprises an isolation between the conductor and/or a contact thereof that is exposed at the second side, and the first areas of the doped polysilicon layers. Several implementations are feasible for generating such an electrical isolation. According to a first one thereof, the doped polysilicon layer is removed outside the first areas. This generates sufficient distance. Preferably, an insulating layer, such as an oxide or a nitride, is deposited on the second side prior to the provision of the metallic conductor. According to a second implementation, an insulating layer is deposited on top of the polysilicon layer, especially in a fourth area. The through-hole is generated within said fourth area, and the metal conductor is then provided. A metal contact terminating the conductor—constituting part of the conductor or being a separate element—is then defined on top of the insulating layer within the fourth area. The provision of the insulating layer may be effected in various manners. One suitable option is printing the insulating layer, for instance by screen printing. One further implementation resides in the use of a so-called electrically insulating polymer paste. Such a paste is for instance based on ceramic materials. As any conductive paste conventionally used in solar cell manufacture, such as paste is able to withstand a final anneal, and/or be converted therein to an inorganic material.

According to a further embodiment, a passivation is applied onto the silicon layer(s), such as the emitter contact layer and the base contact layer. This passivation comprises in one embodiment a silicon nitride layer. In an alternative embodiment, the passivation may contain a silicon oxynitride. In a further embodiment, the passivation comprises an oxide layer, such as a thermal oxide, and a nitride or oxynitride layer. The passivation may further contain a multiple layer comprising a nitride layer, an oxide layer and another nitride layer. In again a further embodiment, the passivation is applied both to the first side and to the second side. This is most suitably done in a chemical vapour deposition process, for instance a phase enhanced chemical vapour deposition process. The application of a passivation including a nitride layer is deemed suitable, as it may be used as an anti-reflection layer on the first side, and for the provision of a buffer layer on top of the polysilicon. Such a buffer layer is particularly desired when applying contacts in a fire-through technique by means of conductive paste. The buffer layer is deemed to improve adhesion. Moreover, hydrogen will be desorbed from the nitride layer during such a firing-through step. This desorbed hydrogen may migrate into the tunnel oxide, which will improve the quality thereof.

Most preferably, the passivation is locally opened and metal contacts are generated, which extend to the polysilicon material. If desired, a contact material may be applied first. Such a contact material most suitably forms a silicide with the polysilicon. The contact material is for instance a metal or alloy, such as nickel, tungsten, titanium tungsten, or a conductive oxide or particularly conductive nitride, such titanium nitride or the like. In a further embodiment, the passivation is locally opened by means of a firing-through technique. Herein, firing-through contacts are applied onto the nitride-containing passivation layer on the second side. The contacts will then be fired through the passivation, such that no separate opening of the passivation is required. More particularly, use is made of a silver-based conductive paste

In one further embodiment, the anneal treatment is carried out simultaneously with the formation of the oxide, which is then a thermal oxide. This anneal is then used to recrystallize the amorphized polysilicon and thus to increase the crystallinity of the deposited polysilicon. The anneal is further used to diffuse dopant of opposite polarity, if any into the silicon layer, to (further) diffuse any charge carriers within the semiconductor substrate and to generate the thermal oxide. It is further observed that the formation of this thermal oxide will reduce a thickness of the polysilicon layer. The consumed thickness is suitably at most 10% of the total thickness of the polysilicon layer as deposited.

### BRIEF INTRODUCTION TO THE FIGURES

These and other aspects of the method and the device of the invention will be further elucidated with reference to the FIGURES, wherein:

FIG. 1a-j show in cross-sectional diagrammatical view several stages in a first embodiment of the method;

### DETAILED DESCRIPTION OF ILLUSTRATED EMBODIMENTS

The Figures are not drawn to scale and are merely intended for illustrative purposes. Equal reference numerals in different FIGURES refer to equal or corresponding elements.

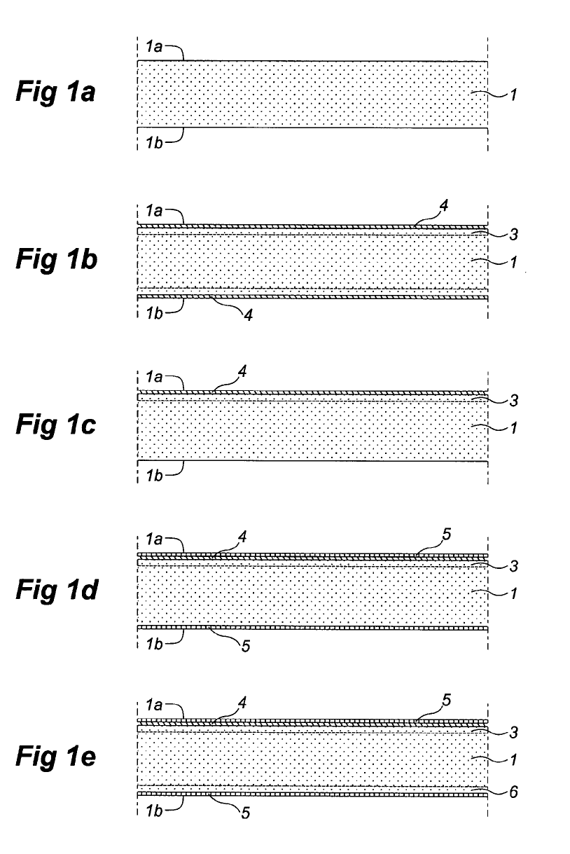

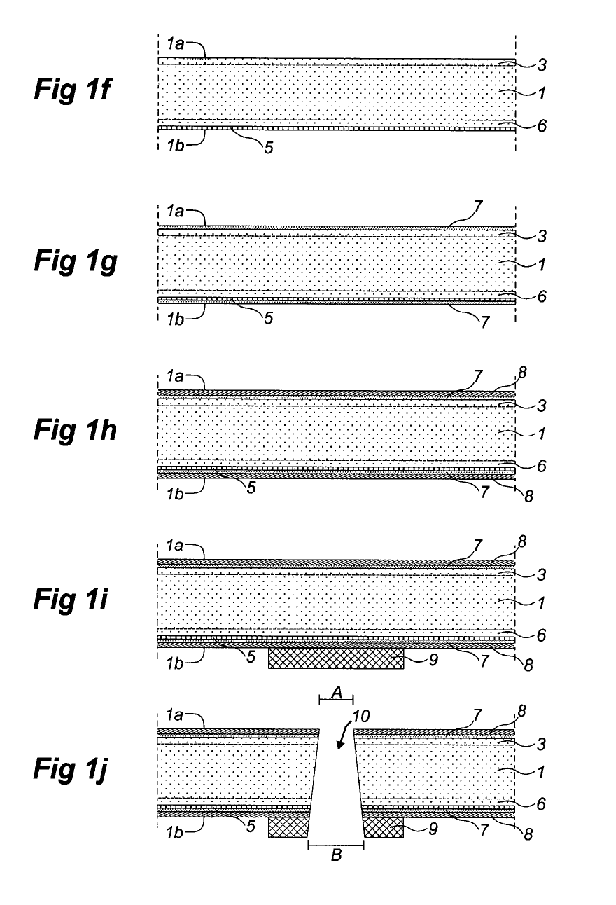

FIG. 1a shows a first stage of a first embodiment of the method of the invention. Herein a semiconductor substrate 1 is provided with a first side 1a and an opposed second side 1b. For sake of clarity, the first side 1a is herein defined as the side that is configured for capturing incoming radiation and will in use be exposed to sunlight. The first side 1a is conventionally textured so as to enhance the capturing of incoming light. This texturing is suitably provided at the beginning of the process. Thus even though not shown, it is to be assumed that the first side 1a has been provided with texture. The semiconductor substrate 1 is preferably a silicon substrate, that is for instance lightly doped as known to the skilled person, with either p-type or n-type doping. Monocrystalline silicon substrates are deemed most beneficial, but other types of substrates are not excluded.

FIG. 1b shows a second stage of this embodiment of the method, wherein the substrate 1 is provided with a dopant layer 4 for generating an electrically conductive region 3 at the first side 1a of the substrate 1. Upon depositing dopant, a silicate glass will be formed, for instance a borosilicate glass or a phosphosilicate glass. In a preferred embodiment, the dopant layer is a borosilicate glass. The electrically conductive region 3 is then doped with boron, which is a preferred example of a p-type dopant. Other p-type dopants are not excluded. The diffusion of the dopant from the dopant layer 4 into the substrate 1 to create the electrically conductive region 3 is carried out by heating. As is shown in this FIG. 1b, the dopant layer 4 is applied on both sides 1a, 1b of the substrate 1, and electrically conductive regions 3 are formed both at the first side 1a and at the second side 1b. This is deemed an efficient implementation, such that the diffusion process may be carried out in a single piece of equipment. Subsequently, as shown in FIG. 1c, the electrically conductive region 3 at the second side 1b of the substrate 1 is removed. This is effected in a one-sided etch treatment as known per se. It will be understood that alternative process order are feasible. For instance, the dopant layer 4 could be removed from the second side 1b prior to the thermal treatment resulting in diffusion.

FIG. 1d shows the substrate 1, again in diagrammatical cross-sectional view, after a subsequent step, wherein a silicon layer 5 is deposited. The deposition of the silicon layer 5 is preferably preceded by generation of a thin dielectric layer. Such a thin dielectric layer is suitably a silicon oxide, but may alternatively be a silicon nitride or a silicon oxynitride. The thin dielectric layer is suitably sufficiently thin to function as a tunnelling layer. This typically requires a thickness of at most 3 nm and preferably at most 1 nm. The tunnelling layer is suitably generated by means of in-situ thermal oxidation, for instance in the low pressure chemical vapour deposition system. Other technologies, such as atomic layer deposition, are however not excluded. The use of a silicon based layer is preferred, particularly in combination with a silicon substrate.

The silicon layer 5 is suitably deposited in a low-pressure chemical vapour deposition (LPCVD) process. The deposition temperature is suitably at least 500° C., for instance in the range of 500-650° C. It is deemed beneficial that the silicon material is at least partially polycrystalline, but that has been found not to be strictly necessary, not even to obtain a sufficient etch selectivity. The thickness of the silicon layer 5 is for instance a thickness of up to 200 nm, for instance 100-200 nm and preferably 50-150 nm. The substrates 1 are preferably loaded in the LPCVD reactor in a front-to-front configuration. Even though limitation of the silicon deposition is not strictly necessary in view of the subsequent etching process, the front-to-front loading is deemed beneficial so as to maximize the number of substrates per reactor.

FIG. 1e shows the substrate 1 after the subsequent step, wherein an implantation is carried out. The implantation is intended for doping of the deposited silicon layer 5. The implantation dose is suitably chosen such that the implanted doping also migrates to the semiconductor substrate 1 and generates a doped layer 6 therein. Generally, it is suitable that the implanted dopant has a polarity that is opposite to that of the dopant introduced into the substrate 1 by means of the dopant layer 4. Thus, when the dopant in the electrically conductive region 3 is p-type, such as boron, the implanted dopant constituting the doped layer 6 will be n-type, such as phosphorus. Generally, it is deemed beneficial that the electrically conductive region 3 constitutes an emitter, while the doped layer 6 constitutes a back surface field (BSF). The depth of implantation may be controlled in the implantation process. As a result, the implantation 6 may be defined to be present both in the substrate 1 and in the silicon layer 5 as from the beginning. Alternatively, the implantation may be controlled to provide the dopant into the silicon layer 5. A subsequent anneal may then diffuse the dopant into the substrate 1. While the implantation into the substrate may initially damage the tunnel dielectric, the tunnel dielectric is repaired in the anneal. There is however no need to carry out such anneal immediately after the implantation. Rather, it is preferably postponed until after the etching treatment of which the result is shown in FIG. 1f.

The implantation is typically carried out in one-sided processing, by providing a ion bombardment from a source. As a consequence, the implantation will at least largely arrive at the second side 1b of the substrate 1. In one implementation, the stack of the dopant layer 4 and silicon layer 5 at the first side 1a of the substrate 1 may be used as a carrier for the substrate 1 in this implantation step, therewith further minimizing the implantation into the silicon layer 5 on the first side 1a of the substrate 1. The dose is chosen to achieve amorphisation of the silicon layer 5 at the second side 1b of the substrate 1. It is not excluded that part of the substrate 1 is also amorphized.

FIG. 1f shows the substrate 1 after the selective etching treatment. As a consequence of the amorphisation and doping, any silicon deposited at the first side 1a of the substrate 1 will be etched away, while the silicon layer 5 at the second side 1b which is amorphized, remains. The etching treatment is suitably carried out by means of wet-chemical etching, and preferably with an alkaline treatment. However, a dry etching treatment is not per se excluded. It has been found that such alkaline treatment is not detrimental for the amorphized and doped silicon layer 5 at the second side 1b. It was found that neither the resistivity (per square) nor the doping profile was modified significantly during the etching step. The etching is suitably carried out at room temperature between 10 and 30° C., but also at higher or lower temperatures, for instance in the range of 0-80° C.

It is observed that the etch selectivity is also achieved between the amorphized and doped silicon layer and an amorphous silicon layer, particularly when using phosphorus ions for the ion implantation. The etch selectivity is further achieved between amorphized silicon layer on the one hand, and recrystallized silicon after amorphisation. The exact mechanism of the etch selectivity is not known. Possibly, the ion implantation removes a native oxide and modifies the crystal lattice, for instance by forming a kind of alloy, more particularly an allow between Si and P and/or Si and As. It may then be more difficult for the alkaline etch, particularly based on hydroxide ions, to attack the silicon, for instance because of selective oxidation of the dopant (especially phosphorus), or because that the free electrons of the oxygen are not able to attack a Si—Si molecular orbital.

Subsequently, a second etch step is carried out, wherein the dopant layer 4 is removed. Because the dopant layer comprises silicate glass, it can be selectively etched relatively to the doped silicon layer.

FIG. 1g shows the substrate 1 after a subsequent process step, which involves the formation of a thermal oxide 7. This thermal oxide 7 is provided both at the first side 1a and at the second side 1b of the substrate. Simultaneously with forming the thermal oxide, the doped silicon layer 7 is recrystallized. Subsequently, a nitride layer is applied on the first and the second sides 1a, 1b. This nitride layer is more particularly a silicon nitride layer. It is generated so as to constitute part of the passivation, and to act as an anti-reflection coating (ARC). FIG. 1h shows the substrate 1 with this nitride layer 8. Alternatively, the silicon nitride layer may be applied in a one-sided process. This allows that the silicon nitride layer 8 on the first side 1a is optimized for its antireflection properties, while the silicon nitride layer 8 on the second side 1b is optimized for passivation and ability to withstand solder, conductive adhesive and other assembly materials. Furthermore, in such an embodiment, the layers 8 on first side 1a and second side 1b do not need to contain the same material.

FIG. 1i and FIG. 1j show a further step in the process, which involves the formation of a conductor extending through the substrate 1. Such formation is an option of the present method. The embodiment shown in these FIGURES is advantageous for minimizing patterning steps. In fact, in accordance with this method, the implantation step may be carried out mask-less. The only patterning step is shown in this FIG. 1i, which relates to the provision of an insulating layer 9. The insulating layer 9 is most suitably deposited by printing, although a photolithographic process is not excluded. However, the printing is deemed to have major advantages: first, the number of steps is reduced. Secondly, screen-printing allows the deposition of the insulating layer 9 in a sufficient thickness, for minimizing parasitic capacitive interaction with the polysilicon layer 5. A suitable thickness is for instance in the order of 1 micron or more. Photoresists with such a thickness have the disadvantage that the irradiation process may not extend through the photoresist layer, with the risk that part thereof is maintained. A suitable material is for instance a polymer paste, though alternatives are not excluded. For instance, use can be made of a two-step process, wherein first a surface modifier is applied, after which the insulating layer is applied. It is evidently feasible that the screen-printed material constitutes a resist which defines cavities for deposition of materials, such as an insulating material. When using such a resist, it appears beneficial that the resist generates at once the structure for a plurality of subsequent deposition steps. Another such deposition step is for instance the generation of metal contacts extending to the polysilicon layer 5. The insulating layer 9 is herein defined in a fourth area.

FIG. 1i shows the subsequent stage, wherein a through-hole 10 is provided within the fourth area. In this manner, a contact—also known as via—may be applied extending from the first side 1a to the second side 1b. The solar cell may thereafter be finalized by deposition of conductors. In one suitable embodiment, conductive paste is used thereto, as is common in the field of solar cell manufacture.

Experiments were carried out with test samples. Herein, a Czochralski-type and polished n-doped monocrystalline silicon substrate of a thickness of 200 μm was inserted into an LPCVD furnace and provided with a tunnel oxide of approximately 2 nm and a silicon layer, both on the first side and the second side. Deposition temperature was at about 580° C. and the silicon layers were deposited in a thickness of 100-120 nm. The silicon layers were thereafter treated by ion implantation to obtain a doping level of about 2E20 cm⁻³. The silicon layer was recrystallized and thermally oxidized, to generate a thermal oxide with a thickness of about 8 nm. Thereafter, a PECVD SiNx:H layer was deposited to a thickness of 80 nm, on both side of the substrate. A rapid firing step was carried out to release hydrogen out of the nitride.

Characterisation of the passivation quality was carried out by means of a QSSPC measurement using a WCT-120 tool available from Sinton Instruments. The passivation performance assessed by QSSPC measurement on test samples with an Phosphorus implant doped polysilicon layer on both sides showed that the lifetime reached 7.2 ms at an injection level of 1E15 cm⁻³, while the recombination current J₀ became as low as 1.8 fA/cm² per side extracted near to a 1E16 cm⁻³ injection level. These values demonstrate the high passivation quality that can be obtained with n-type doped LPCVD polysilicon layers. The implied V_{oc} was around 740 mV.

Thus, in summary, the invention relates to a process for manufacturing a solar cell, which is provided with a so-called passivated contact based on a layer of polysilicon layer onto a tunnel dielectric, such as a tunnel oxide. The process for manufacturing a solar cell provides for so-called passivated contacts based on a layer of polysilicon layer onto a tunnel dielectric, such as a tunnel oxide. Herein, a treatment is carried out on the polysilicon layer as deposited by ion implantation so as to render it to an amorphized state. This ion implantation simultaneously allows the provision of doped regions, particularly of phosphorus. Selectively recrystallized areas and untreated areas are then removed by etching, including unintentionally deposited polysilicon at the first side of the substrate. Further process steps may be carried out prior to or subsequent to this provision of a patterned and ion implanted polysilicon layer, so as to provide for instance a cell with a metal wrap-through (MWT) structure.

The electrically conductive region in the first side of the substrate is suitably provided in a diffusion process. The resulting silicate glass, for instance a borosilicate glass is preferably removed from the first side after the implantation step. In this manner, the borosilicate glass acts as a protective layer to fully prevent that the implanted dopant reaches the first side of the substrate.

In one embodiment, the method further comprises the provision of a dielectric layer on the second side prior to deposition of the silicon material, said dielectric layer being sufficiently thin to act as a tunnel dielectric, and wherein the treatment step is carried out so that the implanted ions further create a doped layer in the substrate adjacent to the tunnel dielectric. This is particularly suitable if the implanted dopant is phosphorus.

In one embodiment, the silicon material is further deposited at the first side, which silicon material forms part of the second areas and is etched away in the etching step. Thus, the silicon deposited can be carried out in conventional manner, more especially in an LPCVD reactor, without need for single sided deposition. This enhances productivity, also because it allows for a large amount of substrates to be processed at the same time in the LPCVD reactor.

In one embodiment, the treatment further comprises selective recrystallisation of part of the amorphized and doped silicon layer at the second side, so as to create second crystalline areas at the second side, which are selectively removed in the etching step. This has the advantage that the ion implantation may be carried out in a mask-less manner, while yielding a doping pattern on the second side.

In one embodiment, the method further comprises the step of annealing the substrate, which step is carried out after the etching step.

In one embodiment, the method further comprises the provision of a metallic conductor extending in a through-hole from the first to the second side of the substrate, and terminating at the second side of the substrate in a contact that is electrically isolated from the doped silicon layer by means of an electrically insulating layer. Suitably, the insulating layer is patterned and arranged adjacent to metal contacts connected to the doped silicon layer.

1. A method of manufacturing a solar cell comprising the steps of:
providing a semiconductor substrate with a first and a second side, which first side is intended for receiving incident light;
providing an electrically conductive region adjacent to the first side by means of diffusion of a dopant of a first conductivity type, preferably boron;
providing a dielectric layer on the second side, which dielectric layer is sufficiently thin to act as a tunnel dielectric;
depositing by means of chemical vapour deposition silicon material on the dielectric layer, which forms a silicon layer at least on the second side and is further deposited at the first side;
treating at least part of the silicon layer at the second side, which treatment comprises ion implantation into the exposed silicon layer at the second side of dopant species of a second conductivity type opposed to the first conductivity type, which dopant species contains phosphorus, so as to obtain first areas of the deposited silicon material that are amorphized and doped and second untreated and/or crystalline areas in the deposited silicon material;
removing the second areas of the silicon material by etching, wherein the silicon material on the first side forms part of the second areas that is etched away.

2. The method as claimed in claim 1, wherein the electrically conductive region adjacent to the first side is provided by diffusion of a dopant of a first conductivity type into both sides and is followed by removing the second conductivity-type doped layer from the second side by a single sided etching process.

3. The method as claimed in claim 1, wherein the silicon layer is deposited by means of low-pressure chemical vapour deposition (LPCVD).

4. The method as claimed in claim 3, wherein the tunnel dielectric is thermally grown inside a low-pressure chemical vapour deposition (LPCVD) reactor.

5. The method as claimed in claim 3, wherein the silicon layer is deposited so as to be at least partially polycrystalline, preferably at a temperature in the range of 500-650° C., more preferably 580-620° C.

6. The method as claimed in claim 2, wherein the treatment step, and particularly the implantation thereof, is carried out so that the implanted ions further create a doped layer in the substrate adjacent to the tunnel dielectric.

7. The method as claimed in claim 1, wherein the treatment further comprises selective recrystallisation of part of the amorphized and doped silicon layer at the second side, so as to create second crystalline areas at the second side, which are selectively removed in the etching step.

8. The method as claimed in claim 1, wherein the removal of the second areas of the silicon material by etching is carried out with wet-chemical etching, preferably with an alkaline solution.

9. The method as claimed in claim 1, wherein the ion implantation at the second side is carried out mask-less, particularly by using directional ion beams and without any masking of said ion beams.

10. The method as claimed in claim 1, wherein an anneal treatment is carried out after the removal of the second areas simultaneously with formation of a thermal oxide at the first side and at the second side, in which anneal treatment the amorphised and doped silicon material of the first areas is recrystallised.

11. The method as claimed in claim 10, wherein a passivation including a silicon nitride layer is applied to the first side and to the second side, said passivation being used as anti-reflection layer on the first side and as a buffer layer on the second side, which application of a silicon nitride layer preferably comprises a deposition of a hydrogenated silicon nitride (SiNx:H) layer in a plasma-enhanced chemical vapour deposition process (PECVD).

12. The method as claimed in claim 11, wherein contacts are applied to the recrystallised silicon layer in a fire-through technique by means of conductive paste, particularly by means of screen printing conductive paste and applying a rapid fire anneal during which the paste etches through the silicon nitride and the thermal oxide layers.

13. The method as claimed in claim 12, wherein the application of contacts in the fire-through technique is carried out such that hydrogen will be desorbed from the hydrogenated silicon nitride layer and migrates into the tunnel dielectric, particularly the tunnel oxide.

14. The method as claimed in claim 1, further comprising the steps of:
applying an electrically insulating layer in a fourth area on the second side;
providing a through-hole through the substrate, which through-hole is arranged within the fourth area;
applying electrically conductive material extending from the first side to the second side, and defining a contact on the second side within the fourth area.

15. A solar cell comprising a semiconductor substrate with a first side and an opposed second side, which semiconductor substrate is provided with a first electrically conductive region of a first conductivity type adjacent to the first side, preferably containing boron dopant and a second electrically conductive region of a second conductivity type adjacent to the second side, said region containing phosphorus, which first electrically conductive region constitutes an emitter and which second electrically conductive region constitutes a back surface field, wherein a doped silicon layer overlies said second electrically conductive region and is separated from the second electrically conductive region through a tunnel dielectric, and at least one metal contact is coupled to said doped silicon layer,
wherein that the doped silicon layer is a recrystallized, ion-implanted layer and that the second electrically conductive region is doped by ion implantation.

16. The solar cell as claimed in claim 15, wherein the doped silicon layer is obtained by low-pressure chemical vapour deposition, preferably at a temperature of 500-650° C., for instance 520-600° C., or 580-620° C.

17. The solar cell as claimed in claim 15, wherein the dopant concentration ratio between the doped silicon layer and the second electrically conductive region is at least two, more preferably at least 10, for instance between 100 and 1000.

18. The solar cell as claimed in claim 15, wherein a thermal oxide is present on the first and the second side, on top of which a passivation including a silicon nitride layer is present, said passivation being used as anti-reflection layer on the first side and as a buffer layer on the second side, and wherein the metal contact to said doped silicon layer is based on a conductive paste applied by means of a fire-through technique.

19. The solar cell as claimed in claim 15, wherein the doped silicon layer is patterned in accordance with a predefined pattern, and is absent outside said pattern.
